(19) United States
(12) Patent Application Publication
(10) Pub. No.: US 2025/0207246 A1
(43) Pub. Date: Jun. 26, 2025

(54) REDUCING CAPACITANCE IN SEMICONDUCTOR DEVICES

(71) Applicant: Lam Research Corporation, Fremont, CA (US)

(72) Inventors: Ian John CURTIN, Portland, OR (US); Douglas Walter AGNEW, Portland, OR (US); Zhe GUI, Beaverton, OR (US); Tobias PEISSKER, Bertem (BE); Bart J. VAN SCHRAVENDIJK, Palo Alto, CA (US)

(21) Appl. No.: 18/847,683

(22) PCT Filed: Mar. 16, 2023
(86) PCT No.: PCT/US2023/064578

§ 371 Date: Sep. 17, 2024

Related U.S. Application Data
(60) Provisional application No. 63/365,425, filed on May 27, 2022.
(60) Provisional application No. 63/269,604, filed on Mar. 18, 2022.

(51) Int. Cl. C23C 16/04; H01L 21/02

(52) U.S. Cl. CPC C23C 16/045; H01L 21/02211; H01L 21/02274; H01L 21/0228

(57) ABSTRACT

Methods of forming air gaps in hole and trench structures using plasma enhanced atomic layer deposition (PEALD) are disclosed. The methods may be used to form buried voids, i.e., voids for which the top is below the top of the adjacent features. In some embodiments, the methods are to reduce intra-level capacitance in semiconductor devices.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Air is a strong dielectric with its dielectric constant k being close to unity. Air gaps may be formed in semiconductor device structures to provide an ultra-low-k material separating conductors.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods of forming air gaps in hole and trench structures are disclosed. The methods may be used to form buried voids. Buried voids are voids that are below the top of adjacent features. The methods include plasma-enhanced deposition of dielectric material using a dilute reactant flow during plasma operation. In some embodiments, the methods involve dilution of a reactive gas species during a plasma conversion operation of a plasma-enhanced atomic layer deposition (PEALD) process. This results in starving reactive ions and/or radicals at the bottom of the feature, leading to a non-conformal growth that preferentially deposits near the top of the feature. Repeating this sequence leads to the formation of air gaps.

One aspect of the disclosure relates to a method including: providing a structure including features and an open gap between the features, the open gap including sidewall and bottom surfaces; and performing multiple plasma enhanced atomic layer deposition (PEALD) cycles, each cycle including: exposing the structure to a dose of a silicon-containing precursor to allow the silicon-containing precursor to adsorb on sidewall and bottom surfaces of the open gap; and exposing the adsorbed silicon-containing precursor to a plasma generated from a process gas including a co-reactant and one or more dilution gases, to react the co-reactant with the adsorbed silicon-containing precursor and form a dielectric material, wherein the dielectric material is preferentially formed near a top of the open gap, wherein a volumetric flow rate ratio of the one or more dilution gas to the co-reactant is at least 5:1.

In some embodiments, the method further includes closing the open gap with deposited dielectric material, thereby forming a closed air gap between the features. In some embodiments, a top of the closed air gap is below tops of the features. In some embodiments, a top of the closed air gap is at least 5 nanometers below tops of the features.

In some embodiments, the method further includes purging a chamber housing the structure between (a) and (b). In some embodiments, a volumetric flow rate ratio of the one or more dilution gases to the co-reactant is at least 10:1. In some embodiments, a volumetric flow rate ratio of the one or more dilution gases to the co-reactant is at least 20:1. In some embodiments, a volumetric flow rate ratio of the one or more dilution gases to the co-reactant is between 5:1 and 50:1. In some embodiments, the co-reactant is an oxygen-containing gas. In some embodiments, the co-reactant is nitrous oxide (N2O) and/or oxygen (O2). In some embodiments, the co-reactant is nitrogen (N2). In some embodiments, a duration of (a) in each cycle is at least twice a duration of (b). In some embodiments, the open gap has a first area and the closed air gap occupies at least 80% of the first area. In some embodiments, the closed air gap occupies at least 90% of the first area.

Another aspect of the disclosure relates to method including: providing a structure including features and an open gap between the features, the open gap having a first area and including sidewall and bottom surfaces; and performing multiple plasma enhanced atomic layer deposition (PEALD) cycles to deposit dielectric material preferentially at a top of the open gap, forming a closed air gap between the features, each cycle including: exposing the structure to a dose of a silicon-containing precursor to allow the silicon-containing precursor to adsorb on sidewall and bottom surfaces of the open gap; and exposing the adsorbed silicon-containing precursor to a plasma generated from a process gas including a co-reactant and one or more dilution gases, to react the co-reactant with the adsorbed silicon-containing precursor and form a dielectric material, wherein the closed air gap is formed without etch or inhibition operations and the closed air gap occupies at least 80% of the first area.

In some embodiments, closed air gap occupies at least 90% of the first area. In some embodiments, a volumetric flow rate ratio of the one or more dilution gases to the co-reactant is at least 10:1. In some embodiments, a volumetric flow rate ratio of the one or more dilution gases to the co-reactant is at least 20:1.

These and other aspects are described further below with reference to the Figures.

### BRIEF DESCRIPTION OF DRAWINGS

FIG. 1 is a process flow diagram showing an example method of forming an air gap.

FIG. 2 includes cross-sectional schematic depictions of features before and after forming an air gap.

FIG. 3 is a process flow diagram for a single plasma enhanced atomic layer deposition cycle that implemented as part of a method of forming an air gap.

FIG. 4 is an example of a gas and plasma RF timing sequence at a plasma-enhanced atomic layer deposition (PEALD station that may be implemented in accordance with embodiments described herein.

FIG. 5 includes examples of cross-sectional schematic depictions of a feature before and after forming an air gap.

FIG. 6 includes examples of cross-sectional schematic depictions of a feature with an air gap before and after planarization.

FIG. 7 is a schematic illustration of an embodiment of an atomic layer deposition (ALD) process station that may be used to perform methods described herein.

FIG. 8 is a schematic illustration of an embodiment of a multi-station processing tool that may be used to perform methods described herein.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Methods of forming air gaps in hole and trench structures are disclosed. An air gap is a closed void in a hole, trench, or other recess that contains air. In some embodiments, the methods are used to reduce intra-level capacitance in semiconductor devices. The methods include plasma-enhanced deposition of dielectric material using a dilute reactant flow during the plasma operation.

In some embodiments, the methods involve dilution of a reactive gas species during a plasma conversion operation of a plasma-enhanced atomic layer deposition (PEALD) process. This results in starving reactive ions and/or radicals at the bottom of the feature, leading to a non-conformal growth that preferentially deposits near the top of the feature. Repeating this sequence leads to the formation of an air gap. As discussed further below, the conformality of the process and the location of the air gap can controlled by various parameters including reactive species chemistry, gas flow ratios, pressure, and plasma power. Well-placed air gaps across different structures and feature sizes can be formed.

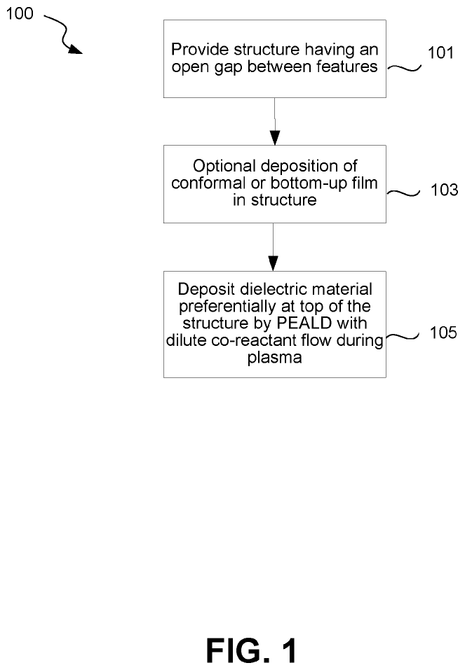

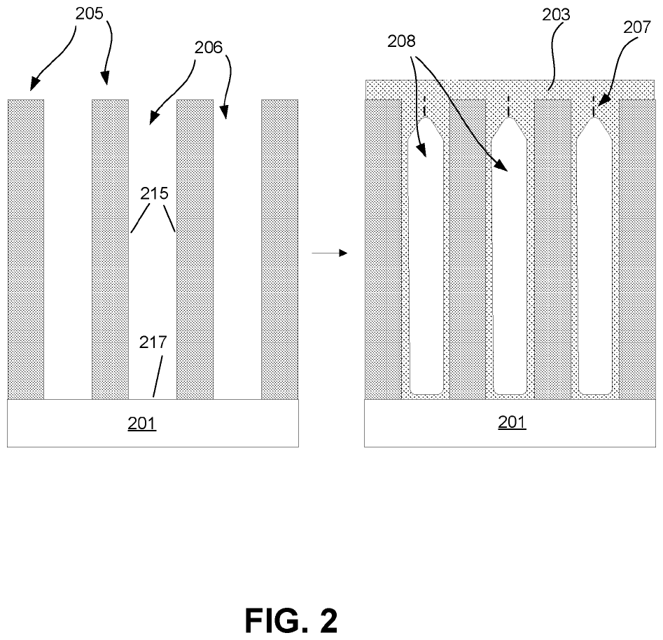

FIG. 1 is a flow chart showing an example method 100 of forming an air gap. First, in an operation 101, a structure having an open gap between features is provided. The structure can be a hole or trench structure or other structure in which an air gap is to be formed between two features, which can be conductive features, dielectric features, semiconducting features, etc. An example of a structure is shown in FIG. 2, discussed further below.

In some embodiments, the methods are used to reduce intra-level capacitance in semiconductor devices. However, they may also be used to form air gaps in any appropriate context, including forming air gaps in metal film or layers and forming air gaps in MEMS devices. Examples of semiconductor structures include interconnects, conductive lines, or other conductive features. The method also may be implemented in any context in which air gaps capped by dielectric film between features are useful. Examples of structures include 3D NAND structures such as slits, DRAM structures such as bitline structures, metal lines in back end of line (BEOL), and logic gates.

The structures are characterized by having two or more adjacent features with an open gap between the features. In many implementations, the features are conductive features, with the air gap to be formed providing very low k dielectric and reducing parasitic capacitance. However, the sidewalls surfaces of the features may include any appropriate material including conductive, dielectric, or semiconducting materials or any combination of these. For example, the structure may be copper (Cu) lines coated with a silicon carbide (SiC) film. The dimensions of the structure depend on the particular application. For example, an incoming DRAM structure may have a gap 25-50 nm wide and 300-800 nm deep and an incoming 3D NAND structure may be 50-100 nm wide and 5-14 microns deep. However, the methods described herein are not limited to any particular structure dimension, feature composition, or sidewall surfaces. In some embodiments, the methods may be implemented in applications in which other techniques for forming air gaps (such as deposition and removal of a sacrificial material) are difficult to implement. The structure is typically provided to a deposition chamber.

Next, an optional conformal or bottom-up deposition of a material in the structure is performed in an operation 103. The material may the same or a different material than that which will be formed at the top of the structure in subsequent operations. The material may be deposited to achieve a particular placement and/or geometry of the air gap. For example, if the air gap bottom is designed to be 100 Å above the bottom of the structure, 100 Å of material may be deposited at the bottom of the structure.

In some embodiments, a conformal liner layer of material is formed. A conformal deposition process such as PEALD may be used for conformal deposition. In some embodiments, operation 103 is omitted.

In a PEALD process, an adsorbed silicon-containing precursor (or other dielectric precursor) is reacted with a co-reactant delivered in a plasma. For example, an oxidizing plasma may be used to form a silicon oxide film. The plasma may be referred as a conversion plasma and the operation of exposing the dielectric precursor to the plasma may be referred to as a plasma conversion operation.

In an operation 105, dielectric material is preferentially deposited at the top of the structure by PEALD using a dilute co-reactant flow during the plasma conversion operation. This gas dilution results in a co-reactant starved conversion, where most of the reactive plasma species are consumed at or near the top of the structure. Few reactive species reach the bottom of the structure, resulting in little growth. The PEALD process preferentially deposits dielectric material at the top of the structure. Sidewall growth at the top of the structure closes off the structure, leaving an air gap below.

FIG. 2 shows an example of a structure including features 205 and open gaps 206 on a substrate 201 before and after deposition. The features 205 may be, for example, metal contacts. The open gaps 206 are between the features 205 and have sidewall surfaces 215 and a bottom surface 217. The sidewall surfaces 215 extend from the opening and are connected by the bottom surface 217. The substrate 201 may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to form structures with air gaps on other substrates, such as glass, plastic, and the like, including in the fabrication of microelectromechanical (MEMS) devices.

Dielectric material 203 is deposited in the open gaps 206 by a PEALD method using a dilute reactant gas. Most of the reactive plasma species are consumed at the top of each feature 205 of the structure. Dielectric material 203 is deposited preferentially at the top of the structure. As deposition occurs, the sidewalls surface 217 and bottom surface 215 of an open gap 206 changes, with the deposited material forming the boundaries of the open gap 206. Growth from each sidewall of a feature 205 eventually meets, closing off the feature at 207. As a result, closed air gaps 208 are formed between the features 205.

In some embodiments, the deposition process is controlled such that the tops of the air gaps 208 are below the top of the features 205 as shown in FIG. 2.

The air gaps that are formed may occupy most of the volume of the incoming gap prior to deposition, e.g., at least 60%, at least 70%, at least 80%, at least 90%, or at least 90% of the original gap. This can also be characterized as the percentage volume occupied by air relative to the total volume occupied by air and solid material between the features. The area of the original gap can be determined by considering a plane connecting the feature tops at the top of the gap.

For example, to reduce capacitance between metal lines, most (e.g., at least 80% or 90%) of the original gap may be air. The top of the air gap may be at least about 5 nm below the feature top to allow for some margin after a subsequent planarization.

In some embodiments, a thin layer of dielectric material is deposited throughout the feature including on the bottom and lower sidewall surfaces. This encapsulates the air gap and may be deposited during the PEALD process.

Air gaps may be formed in large gaps. For example, an incoming gap (e.g., a slit or memory hole) in a 3D NAND structure may be between 50-100 nm wide and 5-14 microns deep. Dielectric material may be deposited to a depth of about 500 nm, with the gap empty (filled with air) below that. About 500 nm of dielectric material may be deposited above the plane of the features. An incoming gap in DRAM structure may be 25-50 nm wide by 300-800 nm deep. Dielectric material may be deposited to a depth of about 30-50 nm, with the gap empty below that.

While the description herein refers to air gaps, the methods described herein may be used to form gaps occupied by any gas between features by performing the method in the appropriate environment.

In some embodiments, one or more etch and/or inhibition operations may be performed during or before the process shown in FIG. 1. However, in some embodiments, an air gap is formed using PEALD without any inhibition or etch operations before and/or during the PEALD process.

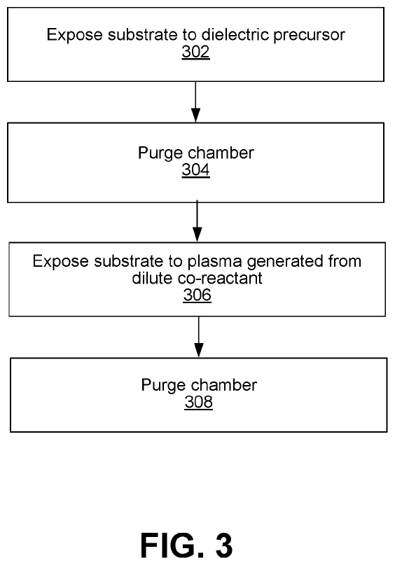

Operation 105 generally uses multiple PEALD cycles. FIG. 3 is a process flow diagram for a single PEALD cycle that may be implemented as part of operation 105 in FIG. 1 to preferentially deposit dielectric material at the top of a structure.

ALD is a technique that sequentially deposits thin layers of material. ALD processes use surface-mediated deposition reactions to deposit films on a layer-by-layer basis in cycles. As an example, an ALD cycle may include the following operations: (i) delivery/adsorption of a precursor, (ii) purging of the precursor from the chamber, (iii) delivery of a second reactant and, for PEALD processes, plasma ignition, and (iv) purging of byproducts from the chamber.

In one example of an ALD process, a substrate surface that includes a population of surface-active sites is exposed to a gas phase distribution of a first precursor, such as a silicon containing precursor, in a dose provided to a chamber housing the substrate. Molecules of this first precursor are adsorbed onto the substrate surface, including chemisorbed species and/or physisorbed molecules of the first precursor. It should be understood that when a compound is adsorbed onto the substrate surface as described herein, the adsorbed layer may include the compound as well as derivatives of the compound. For example, an adsorbed layer of a silicon containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen containing gas, is introduced to the chamber so that some of these molecules react with the first precursor adsorbed on the surface. In some processes, the second reactant reacts immediately with the adsorbed first precursor. In other embodiments, the second reactant reacts only if a source of activation such as plasma is applied temporally. The chamber may then be evacuated again to remove unbound second reactant molecules. As described above, in some embodiments the chamber may not be completely evacuated. Additional ALD cycles may be used to build film thickness.

Turning to FIG. 3, in an operation 302, the substrate is exposed to a dielectric precursor, to adsorb the precursor onto the surface of the feature. This operation may be self-limiting. In some embodiments, the precursor adsorbs to less than all the active sites on the surface of the feature. The dielectric precursor is often a silicon-containing precursor, though other dielectric precursors may be used. Silicon-containing precursors that may be used are described further below.

In an operation 304, the process chamber is purged to remove any unadsorbed dielectric precursors. In an operation 306, the substrate is exposed to a plasma generated from a dilute co-reactant. Examples include oxygen-containing gases such as oxygen (O₂) and/or nitrous oxide (N₂O) to form an oxide layer, nitrogen (N₂) or ammonia (NH₃) to form a nitride layer, a carbon-containing reactant to form a carbide layer, etc.

In operation 308, the process chamber is purged to remove byproducts from the reaction between the dielectric precursor and the co-reactant. Operations 302 through 308 can be repeated for a number of cycles to deposit the dielectric material to form air gaps as described above. According to various embodiments, any of the process parameters described below may be constant or vary from cycle-to-cycle of the multiple PEALD cycle.

It should be noted that the processes described herein are not limited to a particular reaction mechanism. Thus, the process described with respect to FIGS. 1-3 include all deposition processes that use sequential exposures to dielectric precursors and conversion plasmas, including those that are not strictly self-limiting. The process includes sequences in which one or more gases used to generate a plasma is continuously flowed throughout the process with intermittent plasma ignitions.

The co-reactant in operation 105 or 306 is delivered with more inert gases such as argon (Ar), hydrogen (H₂) and/or helium (He) to dilute it. These are referred to as dilution gases. Example volumetric flow rate ratios of inert gas to co-reactant range from 100:1 to 5:1. Ratios outside this range may be used depending on the topography of the feature. The ratio may be tuned to control placement and size of the air gap, and in some embodiments may be from 50:1 to 5:1 or 20:1 to 5:1 to obtain a large gap below the feature tops.

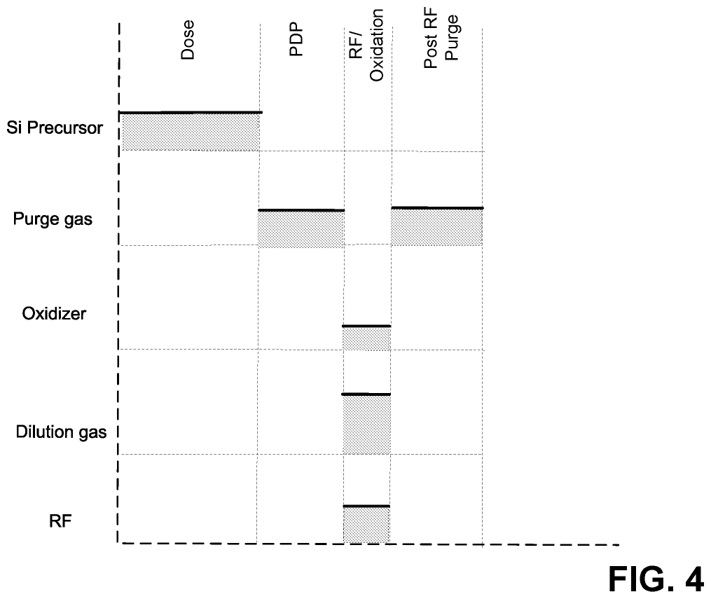

In addition to dilute co-reactant gas, the plasma conversion time may be short to limit reactive species that can diffuse further into the structure. FIG. 4 shows an example timing sequence for deposition of a silicon oxide material to form an air gap. First, during a dose stage, the structure is exposed to a Si-containing precursor. This is followed by a post-dose purge (PDP) in which inert purge gas is flowed. As depicted, the plasma conversion operation (labeled radio frequency (RF)/oxidation) is relatively short, with significantly more dilution gas than oxidant gas flowed. A post RF purge is then performed. In some embodiments, the purge and dilution gases may include the same gas flow. The Si-containing precursor may also be flowed with an inert gas, though at significantly lower dilution than the oxidizer. In some embodiments, the duration of the dose stage is at least twice the duration of the plasma conversion stage.

While extreme dilution of a dielectric precursor dose can be used for non-conformal deposition and used to form air gaps, it tends to lead to high within-wafer non-uniformity. The methods described herein that use extreme dilution of a plasma co-reactant can result in low non-uniformity, for example, less than 5% non-uniformity.

Air gap size and placement may be controlled. As indicated above, in some embodiments, the air gap size is such that it does not extend above the heights of the adjacent features. In some embodiments, the air gap formed is as large as possible while keeping the air gap below the feature top.

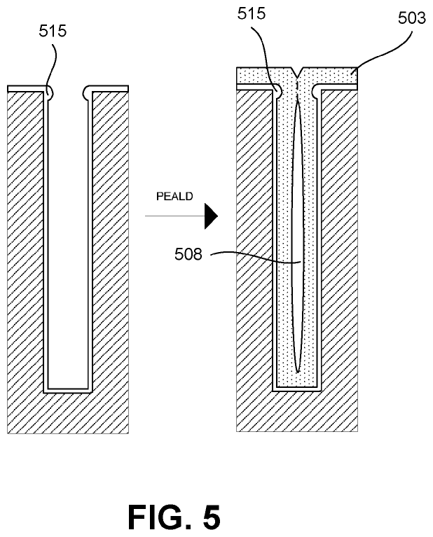

In some embodiments, forming air gaps in gaps having smaller critical dimensions (CDs) may involve use more non-conformal processes (e.g., using higher co-reactant dilution). In addition to CD, feature shape can affect the conditions used to form an air gap having a particular size and placement. Forming an air gap in a structure having an overhang may use less dilution than one with straight sidewalls. This is because the presence of the overhang contributes to the non-conformality, facilitating preferential deposition at the top of the structure and formation of an air gap within the structure. See, e.g., FIG. 5, which shows an overhang 515 in a structure before and after preferential deposition of dielectric material 503 and formation of air gap 508.

Conformality and thus air gap size and placement can be controlled by dilution, chamber pressure, plasma time, plasma power, and choice of co-reactant. For example, when using O₂ as a co-reactant in depositing an oxide, any one or more of: reducing dilution, increasing pressure, increasing RF time, and increasing RF power makes the deposition more conformal and can be used to lower the placement of the air gap. These process conditions can result in a smaller air gap with more sidewall deposition. Similarly, any one or more of: increasing dilution, decreasing pressure, decreasing RF time, and decreasing RF power makes the deposition more non-conformal and can be used to increase the size of the air gap when using O₂.

When using N₂O as oxidizer, any one or more of: reducing dilution, decreasing pressure, decreasing RF time, and decreasing RF power makes the deposition more conformal and can be used to lower the placement of the air gap. These process conditions can result in a smaller air gap with more sidewall deposition. Similarly, any one or more of: increasing dilution, increasing pressure, increasing RF time, and increasing RF power makes the deposition more non-conformal and can be used to increase the size of the air gap when using N₂O.

Air gap placement and size can also be controlled by choice of co-reactant. N₂O, for example, results in a more non-conformal deposition than O₂ at the same dilution. A mix of co-reactants (e.g., O₂ and N₂O) may be used.

For depositing a silicon-containing film, one or more silicon-containing precursors may be used. The silicon-containing precursors may react with a co-reactant to form the silicon-containing film (e.g., SiO₂, SiN, SiON, SiC, SiOC, etc.). Silicon-containing precursors suitable for use in accordance with disclosed embodiments include polysilanes (H₃Si—(SiH₂)ₙ—SiH₃), where n≥0. Examples of silanes are silane (SiH₄), disilane (Si₂H₆), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino) silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In some implementations silicon-containing precursors may include siloxanes or amino-group-containing siloxanes. In some embodiments, siloxanes used herein may have a formula of X(R¹)ₐSi—O—Si(R²)_{b}Y, where a and b are integers from 0 to 2, and X and Y independently can be H or NR³R⁴, where each of R¹, R², R³ and R⁴ is hydrogen, unbranched alkyl, branched alkyl, saturated heterocyclic, unsaturated heterocyclic groups, or combinations thereof. In some embodiments, when at least one X or Y is NR³R⁴, R³ and R⁴, taken together with the atom to which each are attached, form a saturated heterocyclic compound. In some embodiments, the silicon-containing precursors are pentamethylated amino group containing siloxanes or dimethylated amino group containing siloxanes. Examples of amino group containing siloxanes include: 1-diethylamino 1,1,3,3,3,-pentamethyl disiloxane, 1-diisopropylamino-1,1,3,3,3,-pentamethyl disiloxane, 1 dipropylamino-1,1,3,3,3,-pentamethyl disiloxane, 1-di-n-butylamino-1,1,3,3,3,-pentamethyl disiloxane, 1-di-sec-butylamino-1,1,3,3,3,-pentamethyl disiloxane, 1-N-methylethylamino 1,1,3,3,3,-pentamethyl disiloxane, 1-N-methylpropylamino-1,1,3,3,3,-pentamethyl disiloxane, 1 N-methylbutylamino-1,1,3,3,3,-pentamethyl disiloxane, 1-t-butylamino-1,1,3,3,3,-pentamethyl disiloxane, 1-piperidino-1,1,3,3,3,-pentamethyl disiloxane, 1-dimethylamino-1,1-dimethyl disiloxane, 1-diethylamino-1,1-dimethyl disiloxane, 1-diisopropylamino-1,1-dimethyl disiloxane, 1-dipropylamino-1,1-dimethyl disiloxane, 1-di-n-butylamino-1,1-dimethyl disiloxane, 1-di-see butylamino-1,1-dimethyl disiloxane, 1-N-methylethylamino-1,1-dimethyl disiloxane, 1-N methylpropylamino-1,1-dimethyl disiloxan,e 1-N-methylbutylamino-1,1-dimethyl disiloxane, 1 piperidino-1,1-dimethyl disiloxane, 1-t-butylamino-1,1-dimethyl disiloxane, 1-dimethylamino-disiloxane, 1-diethylamino-disiloxane, 1-diisopropylamino-disiloxane, 1-dipropylamino-disiloxane, 1-di-n-butylamino-disiloxane, 1-di-sec-butylamino-disiloxane, 1-N methylethylamino-disiloxane, 1-N-methylpropylamino-disiloxane, 1-N-methylbutylamino-disiloxane, 1-piperidino-disiloxane, 1-t-butylamino disiloxane, and 1-dimethylamino-1,1,5,5,5,-pentamethyl disiloxane.

In addition to a silicon-containing precursor, one or more other gases, including inert gases such as argon, nitrogen, helium, hydrogen, or combinations thereof, may also be flowed during the dose operation. In various embodiments, argon gas may be introduced using a flow rate between about 1 slm and about 20 slm. In some embodiments, nitrogen gas is introduced using a flow rate between about 0 slm and about 30 slm (with the understanding that 0 slm refers to no nitrogen gas being flowed). In some embodiments, hydrogen gas is introduced using a flow rate between about 0 slm and about 5 slm (with the understanding that 0 slm refers to no hydrogen gas being flowed).

The co-reactant is determined in part by the composition of the deposited film. Silicon oxide deposition uses an oxidizing plasma generated, e.g., from oxygen (O₂), nitrous oxide (N₂O), or combinations thereof. Other oxygen-containing compounds such as water (H₂O) may be used.

Silicon nitride (SiN) may be deposited using a N₂ plasma, NH₃ plasma or other nitrogen-containing plasma. In some embodiments, no oxidant is used during SiN deposition. Silicon carbides may be deposited using a carbon-containing co-reactant (e.g., reacting silane with methane). Silicon oxynitrides, silicon oxycarbides, silicon oxycarbonitrides, etc. may be deposited using the appropriate co-reactants.

The co-reactant may also be determined by the degree of conformality it results in during PEALD, as described above.

Plasma energy may be provided to activate the co-reactant into ions and radicals and other activated species, which react with the adsorbed layer of adsorbed precursor and any precursor present in the vapor phase. In various embodiments, the plasma is an in-situ plasma, such that the plasma is formed directly above the substrate surface in the chamber. The in-situ plasma may be ignited at a power per substrate area between about 0.333 W/cm² and about 5 W/cm². For example, the power for four 300 mm wafers may range from about 400 W to about 6000 W.

Examples of chamber pressures can range from 1 to 40 Torr, or 2 to 20 Torr, or 2 Torr to 10 Torr, e.g., 2 to 6 Torr.

Examples of plasma conversion (RF) times range from 0.01 to 0.3 seconds, or 0.5 to 1.5 second, or 0.5 to 1 second. RF plasma time may instead or also be characterized relative to dielectric precursor dose time. Dielectric precursor dose time may be at least 2 times, 3 times, 4 times, or 5 times as long as the plasma conversion time in various embodiments.

Examples of substrate temperatures range from 50° C. to 650° C.

Ranges described herein are inclusive of their end points.

Plasmas may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process. It will be appreciated that the RF field may be coupled via any suitable electrodes.

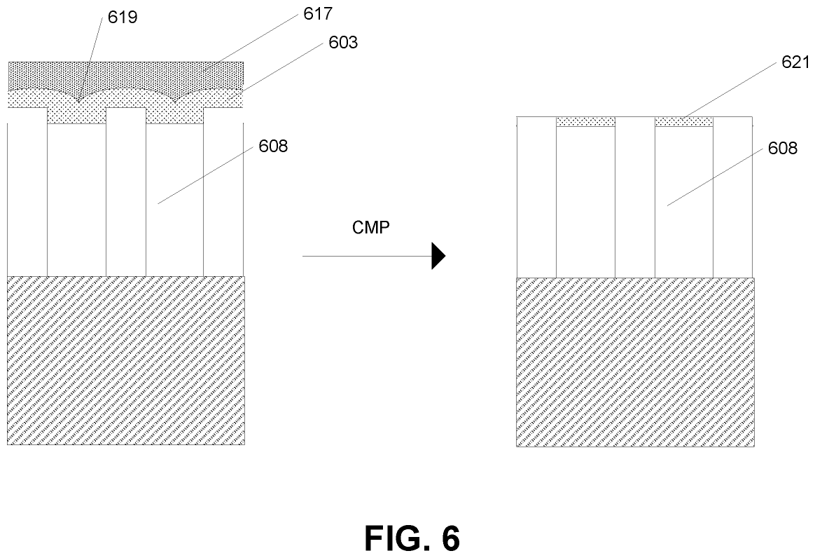

After the air gaps are formed, various operations may be performed. In some embodiments, for example, a cap layer may be deposited over the dielectric material. In some embodiments, dielectric film may be deposited by plasma-enhanced chemical vapor deposition (PECVD). FIG. 6 shows a structure with air gaps 608 formed as described above having a dielectric PECVD film 617 deposited over the dielectric material 603. Indentations 619 that are centered over the air gaps 608 in the dielectric material 603 as a result of the PEALD deposition are smoothed out. Although not shown in FIG. 6, the dielectric PECVD film 617 may include indentations centered over the indentations 619, but their height may be reduced, for example, by at least 20%-90% as compared to those in the dielectric material 603. During etch and CMP steps, deep indentations can cause an uneven amount of material to be removed from the top the structure, resulting in too much material being removed from the filled feature, generating defects which affect device performance. By depositing a cap layer such as dielectric PECVD film 617 ensures that during subsequent planarization, the gap remains filled and a planarized dielectric film 621 results as shown in FIG. 6. In other embodiments, a cap layer may be deposited by thermal CVD. Depositing by CVD (PECVD or thermal CVD) allows for a thick film to be quickly deposited, which preferentially fills in the indentations resulting in a flatter film, reducing the frequency of the generation of defects in subsequent processing. In some operations, the CVD operation is performed in the same chamber as the inhibition and ALD operations. This greatly reduces the number of transfer operations and processing tools. Example thicknesses of a cap layer range from 1-3 kÅ. In some embodiments, thinner layers, e.g., 100-1000 Å, may be deposited.

For purposes of this document, “near” the top of the feature, near the top of the structure, or near the top of the gap, represents an area in the gap located within 25% or within 10% of the total depth as measured vertically from the top of a feature that forms a sidewall of the gap. “Near” the bottom of the feature represents an area in the gap located within 25% or within 10% of the total depth as measured vertically from the feature bottom.

### Experimental

Silicon oxide was deposited into gaps between features using a PEALD process. During the RF plasma, O₂ was the oxidant and flowed with 5000 sccm He and 5000 sccm H₂. O₂ flowrate was varied, with all other deposition parameters constant.

| | O₂ flow | | | |
|---|---|---|---|---|
| | 100 sccm | 200 sccm | 500 sccm | 1000 sccm |
| Average air gap | About | About | About | About |
| area | 370 nm² | 270 nm² | 180 nm² | 150 nm² |

As the H₂:O₂ ratio is decreased from 50:1 to 10:1, the air gap area is reduced. All air gaps were below features for the 10:1 and 5:1 ratios. A similar trend was observed using N₂O as oxidant. N₂O is less conformal than O₂ at the same flow rate, resulting in a larger air gap.

Silicon oxide was deposited into gaps between features using a PEALD process. RF power was varied holding all other parameters constant. During the RF plasma, gas flow was 200 sccm O₂, 5000 sccm He, and 5000 sccm H₂.

| | HF RF power per station | | |
|---|---|---|---|
| | 200 W | 375 W | 750 W |
| Average air | About 270 nm² | About 230 nm² | About 190 nm² |
| gap area | | | |

Air gap area is reduced and conformality increased with increasing RF power. Air gaps can be formed at higher plasma powers, with example powers being 200 W-3000 W for four stations and 300 mm wafers.

### Apparatus

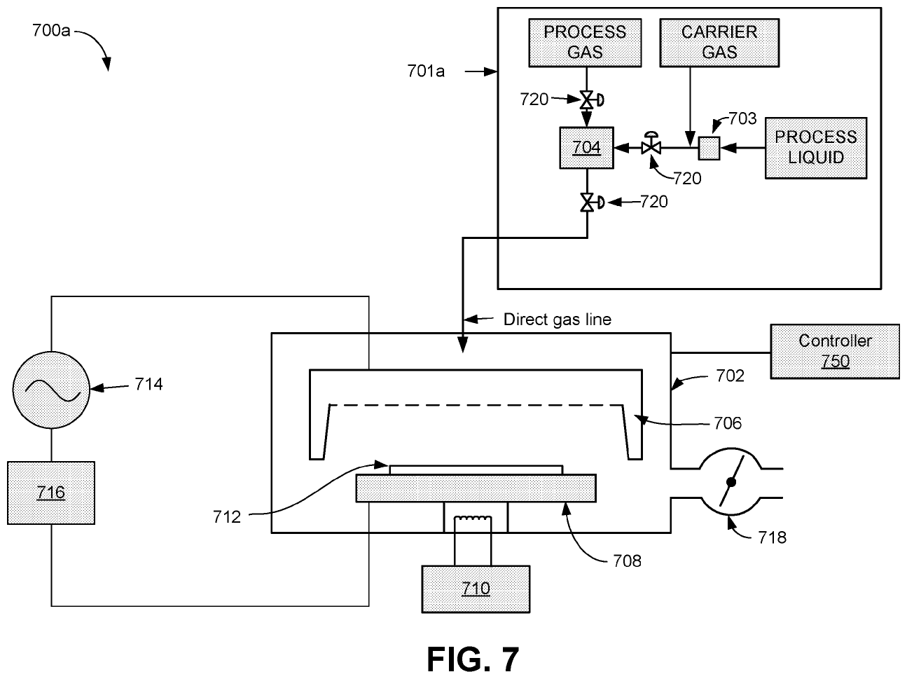

FIG. 7 depicts a schematic illustration of an embodiment of an atomic layer deposition (ALD) process station 700 having a process chamber body 702 for maintaining a low-pressure environment. A plurality of ALD process stations 700 may be included in a common low-pressure process tool environment. For example, FIG. 7 depicts an embodiment of a multi-station processing tool 700. In some embodiments, one or more hardware parameters of ALD process station 700, including those discussed in detail below, may be adjusted programmatically by one or more system controllers 750.

ALD process station 700 fluidly communicates with reactant delivery system 701a for delivering process gases to a distribution showerhead 706. Reactant delivery system 701a includes a mixing vessel 704 for blending and/or conditioning process gases for delivery to showerhead 706. In some embodiments, a process gas may be introduced to the mixing vessel prior to introduction to the chamber body 702, such as if provided with a carrier gas. In some embodiments, a process gas may be directly delivered to the chamber body 702. One or more mixing vessel inlet valves 720 may control introduction of process gases to mixing vessel 704. These valves may be controlled depending on whether a reactant gas, inhibitor gas, or carrier gas may be turned on during various operations. In some embodiments, an inhibitor gas may be generated by using an inhibitor liquid and vaporizing using a heated vaporizer.

As an example, the embodiment of FIG. 7 includes a vaporization point 703 for vaporizing liquid reactant to be supplied to the mixing vessel 704. In some embodiments, vaporization point 703 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 703 may be heat traced. In some examples, mixing vessel 704 may also be heat traced. In one non-limiting example, piping downstream of vaporization point 703 has an increasing temperature profile extending from approximately 100° C. to approximately 150° C. at mixing vessel 704.

In some embodiments, liquid precursor or liquid reactant, such as a silicon-containing precursor, may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 703. In one scenario, a liquid injector may be mounted directly to mixing vessel 704. In another scenario, a liquid injector may be mounted directly to showerhead 706.

In some embodiments, a liquid flow controller (LFC) (not shown) upstream of vaporization point 703 may be provided for controlling a mass flow of liquid for vaporization and delivery to process station 700. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 706 distributes gases toward substrate 712. For example, showerhead 706 may distribute a silicon-containing precursor gas to the substrate 712, or a purge or carrier gas to the chamber body 702, a co-reactant to the substrate 712, and/or a dilution gas to the substrate 712, in various operations. In the embodiment shown in FIG. 7, the substrate 712 is located beneath showerhead 706 and is shown resting on a pedestal 708. Showerhead 706 may have any suitable shape and may have any suitable number and arrangement of ports for distributing process gases to substrate 712.

In some embodiments, a microvolume is located beneath showerhead 706. Practicing disclosed embodiments in a microvolume rather than in the entire volume of a process station may reduce reactant exposure and purge times, may reduce times for altering process conditions (e.g., pressure, temperature, etc.) may limit an exposure of process station robotics to process gases, etc. Example microvolume sizes include, but are not limited to, volumes between 0.1 liter and 2 liters. This also impacts productivity throughput. In some embodiments, the disclosed embodiments are not performed in a microvolume.

In some embodiments, pedestal 708 may be raised or lowered to expose substrate 712 to microvolume 707 and/or to vary a volume of microvolume 707. For example, in a substrate transfer phase, pedestal 708 may be raised to position substrate 712 within microvolume 707. In some embodiments, microvolume 707 may completely enclose substrate 712 as well as a portion of pedestal 708 to create a region of high flow impedance.

Optionally, pedestal 708 may be lowered and/or raised during portions the process to modulate process pressure, reactant concentration, etc., within microvolume 707. In one scenario where process chamber body 702 remains at a base pressure during the process, lowering pedestal 708 may allow microvolume 707 to be evacuated. Example ratios of microvolume to process chamber volume include, but are not limited to, volume ratios between 1:700 and 1:10. It will be appreciated that, in some embodiments, pedestal height may be adjusted programmatically by a suitable computer controller 750.

In another scenario, adjusting a height of pedestal 708 may allow a plasma density to be varied during plasma activation processes. At the conclusion of the process phase, pedestal 708 may be lowered during another substrate transfer phase to allow removal of substrate 712 from pedestal 708.

While the example microvolume variations described herein refer to a height-adjustable pedestal 708, it will be appreciated that, in some embodiments, a position of showerhead 706 may be adjusted relative to pedestal 708 to vary a volume of microvolume 707. Further, it will be appreciated that a vertical position of pedestal 708 and/or showerhead 706 may be varied by any suitable mechanism within the scope of the present disclosure. In some embodiments, pedestal 708 may include a rotational axis for rotating an orientation of substrate 712. It will be appreciated that, in some embodiments, one or more of these example adjustments may be performed programmatically by one or more suitable controllers 750.

Plasmas for ALD processes may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process. It will be appreciated that the RF field may be coupled via any suitable electrodes. Non-limiting examples of electrodes include process gas distribution showerheads and substrate support pedestals. It will be appreciated that plasmas for ALD processes may be formed by one or more suitable methods other than capacitive coupling of an RF field to a gas. In some embodiments, the plasma is a remote plasma, such that second reactant is ignited in a remote plasma generator upstream of the station, then delivered to the station where the substrate is housed.

Showerhead 706 and pedestal 708 electrically communicate with a radio frequency (RF) power supply 714 and matching network 716 for powering a plasma. In some embodiments, the plasma energy may be controlled by controlling one or more of a process station pressure, gas concentrations and partial pressures of gases or gas flow rates, an RF source power, an RF source frequency, and a plasma power pulse timing. For example, RF power supply 714 and matching network 716 may be operated at any suitable power to form a plasma having a desired ion energy. Examples of suitable powers are included above. Likewise, RF power supply 714 may provide RF power of any suitable frequency. In some embodiments, RF power supply 714 may be configured to control high- and low-frequency RF power sources independently of one another. Example low-frequency RF frequencies may include, but are not limited to, frequencies between 0 kHz and 500 kHz. Example high-frequency RF frequencies may include, but are not limited to, frequencies between 1.8 MHz and 2.45 GHZ, or greater than about 13.56 MHZ, or greater than 27 MHz, or greater than 40 MHz, or greater than 60 MHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas. In alternate embodiments, a remote plasma generator may be used.

The ALD process station 700 may also be used for CVD processes.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 750 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., the first precursor such as disilane), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for setting a flow rate of an inert, inhibitor and/or reactant gas which may be the same as or different from the gas used in the first recipe phase, instructions for modulating a flow rate of a carrier gas, and time delay instructions for the third recipe phase. A fourth recipe phase may include instructions for modulating or stopping a flow rate of an inert and/or a reactant gas (e.g., a second reactant such as nitrogen or a nitrogen-containing or oxygen-containing gas), instructions for modulating the flow rate of a carrier or purge gas, and time delay instructions for the fourth recipe phase. It will be appreciated that these recipe phases may be further subdivided and/or iterated in any suitable way within the scope of the present disclosure.

In some embodiments, pedestal 708 may be temperature controlled via heater 710. Further, in some embodiments, pressure control for process station 700 may be provided by butterfly valve 718. As shown in the embodiment of FIG. 7, butterfly valve 718 throttles a vacuum provided by a downstream vacuum pump (not shown). However, in some embodiments, pressure control of process station 700 may also be adjusted by varying a flow rate of one or more gases introduced to the process station 700.

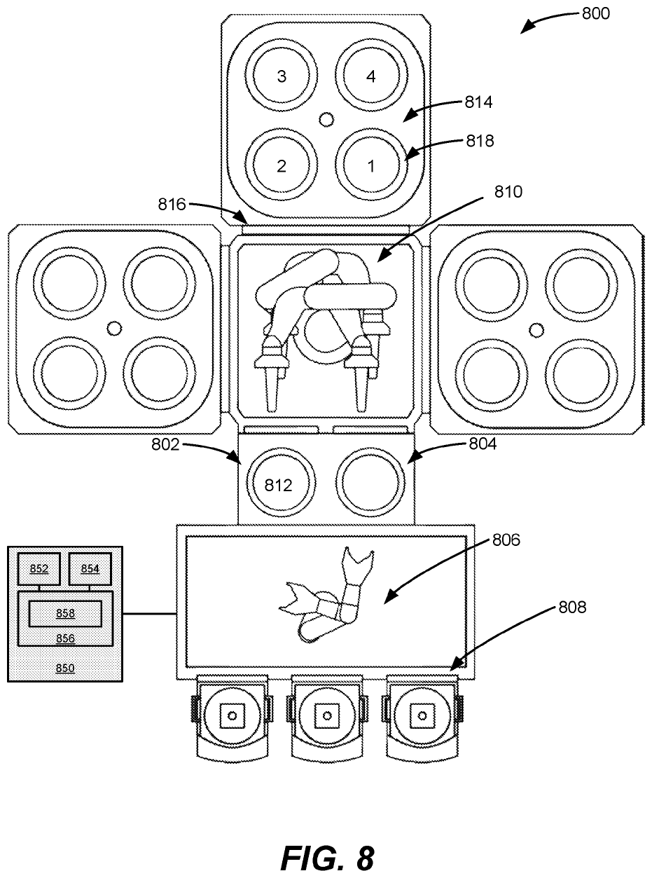

As described above, one or more process stations may be included in a multi-station processing tool. FIG. 8 shows a schematic view of an embodiment of a multi-station processing tool 800 with an inbound load lock 802 and an outbound load lock 804, either or both of which may include a remote plasma source. A robot 806, at atmospheric pressure, is configured to move substrates or wafers from a cassette loaded through a pod 808 into inbound load lock 802 via an atmospheric port. A substrate is placed by the robot 806 on a pedestal 812 in the inbound load lock 802, the atmospheric port is closed, and the load lock is pumped down. Where the inbound load lock 802 comprises a remote plasma source, the substrate may be exposed to a remote plasma treatment in the load lock prior to being introduced into a processing chamber 814. Further, the substrate also may be heated in the inbound load lock 802 as well, for example, to remove moisture and adsorbed gases. Next, a chamber transport port 816 to processing chamber 814 is opened, and another robot 810 places the substrate into the reactor on a pedestal of a first station shown in the reactor for processing. While the embodiment depicted in FIG. 8 includes load locks, it will be appreciated that, in some embodiments, direct entry of a substrate into a process station may be provided. In various embodiments, the soak gas is introduced to the station when the substrate is placed by the robot 806 on the pedestal 812.

The depicted processing chamber 814 comprises four process stations, numbered from 1 to 4 in the embodiment shown in FIG. 8. Each station has a heated pedestal (shown at 818 for station 1), and gas line inlets. It will be appreciated that in some embodiments, each process station may have different or multiple purposes. For example, in some embodiments, a process station may be switchable between an ALD and PEALD process mode. Additionally or alternatively, in some embodiments, processing chamber 814 may include one or more matched pairs of ALD and plasma-enhanced ALD process stations. While the depicted processing chamber 814 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 also depicts an embodiment of a system controller 850 employed to control process conditions and hardware states of process tool 800. System controller 850 may include one or more memory devices 856, one or more mass storage devices 854, and one or more processors 852. Processor 852 may include a CPU or computer, analog and/or digital input/output connections, stepper motor controller boards, etc. In some embodiments, system controller 850 includes machine-readable instructions for performing operations such as those described herein.

In some embodiments, system controller 850 controls the activities of process tool 800. System controller 850 executes system control software 858 stored in mass storage device 854, loaded into memory device 856, and executed on processor 852. Alternatively, the control logic may be hard coded in the system controller 850. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 858 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by process tool 800. System control software 858 may be configured in any suitable way. For example, various process tool component subroutines or control objects may be written to control operation of the process tool components used to carry out various process tool processes. System control software 858 may be coded in any suitable computer readable programming language.

In some embodiments, system control software 858 may include input/output control (IOC) sequencing instructions for controlling the various parameters described above. Other computer software and/or programs stored on mass storage device 854 and/or memory device 856 associated with system controller 850 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 818 and to control the spacing between the substrate and other parts of process tool 800.

A process gas control program may include code for controlling gas composition (e.g., silicon-containing precursor, co-reactant, dilution, and purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 850. The user interface may include a display screen, graphical software displays of the apparatus and/or process conditions, and user input devices such as pointing devices, keyboards, touch screens, microphones, etc.

In some embodiments, parameters adjusted by system controller 850 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 850 from various process tool sensors. The signals for controlling the process may be output on the analog and digital output connections of process tool 800. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 850 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 850 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 850.

In some implementations, the system controller 850 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 850, depending on the processing conditions and/or the type of system, may be programmed to control any of the processes disclosed herein, including the delivery of processing gases and/or inhibitor gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 850 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 650 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 850, in some implementations, may be a part of or coupled to a computer that is integrated with, coupled to the system, otherwise networked to the system, or a combination thereof. For example, the system controller 850 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 850 receives instructions in the form of data, which specify parameters for each of the processing steps to be performed during one or more operations. The parameters may be specific to the type of process to be performed and the type of tool that the system controller 850 is configured to interface with or control. Thus, as described above, the system controller 850 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 850 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The apparatus/process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method comprising:
providing a structure comprising features and an open gap between the features, the open gap including sidewall and bottom surfaces; and
performing multiple plasma enhanced atomic layer deposition (PEALD) cycles, each cycle comprising:
a) exposing the structure to a dose of a silicon-containing precursor to allow the silicon-containing precursor to adsorb on sidewall and bottom surfaces of the open gap; and
b) exposing the adsorbed silicon-containing precursor to a plasma generated from a process gas comprising a co-reactant and one or more dilution gases, to react the co-reactant with the adsorbed silicon-containing precursor and form a dielectric material, wherein the dielectric material is preferentially formed near a top of the open gap, wherein a volumetric flow rate ratio of the one or more dilution gas to the co-reactant is at least 5:1.

2. The method of claim 1, further comprising closing the open gap with deposited dielectric material, thereby forming a closed air gap between the features.

3. The method of claim 2, wherein a top of the closed air gap is below tops of the features.

4. The method of claim 2, wherein a top of the closed air gap is at least 5 nanometers below tops of the features.

5. The method of claim 1, further comprising purging a chamber housing the structure between (a) and (b).

6. The method of claim 1, wherein a volumetric flow rate ratio of the one or more dilution gases to the co-reactant is at least 10:1.

7. The method of claim 1, wherein a volumetric flow rate ratio of the one or more dilution gases to the co-reactant is at least 20:1.

8. The method of claim 1, wherein a volumetric flow rate ratio of the one or more dilution gases to the co-reactant is between 5:1 and 50:1.

9. The method of claim 1, wherein the co-reactant is an oxygen-containing gas.

10. The method of claim 1, wherein the co-reactant is nitrous oxide (N₂O) or oxygen (O₂).

11. The method of claim 1, wherein the co-reactant is O₂ and N₂O.

12. The method of claim 1, wherein the co-reactant is nitrogen (N₂).

13. The method of claim 1, wherein a duration of (a) in each cycle is at least twice a duration of (b).

14. The method of claim 2, wherein the open gap has a first area and the closed air gap occupies at least 80% of the first area.

15. The method of claim 14, wherein the closed air gap occupies at least 90% of the first area.

16. A method comprising:
providing a structure comprising features and an open gap between the features, the open gap having a first area and including sidewall and bottom surfaces; and
performing multiple plasma enhanced atomic layer deposition (PEALD) cycles to deposit dielectric material preferentially at a top of the open gap, forming a closed air gap between the features, each cycle comprising:
a) exposing the structure to a dose of a silicon-containing precursor to allow the silicon-containing precursor to adsorb on sidewall and bottom surfaces of the open gap; and
b) exposing the adsorbed silicon-containing precursor to a plasma generated from a process gas comprising a co-reactant and one or more dilution gases, to react the co-reactant with the adsorbed silicon-containing precursor and form a dielectric material,
wherein the closed air gap is formed without etch or inhibition operations and the closed air gap occupies at least 80% of the first area.

17. The method of claim 16, wherein the closed air gap occupies at least 90% of the first area.

18. The method of claim 16, wherein a volumetric flow rate ratio of the one or more dilution gases to the co-reactant is at least 10:1.

19. The method of claim 16, wherein a volumetric flow rate ratio of the one or more dilution gases to the co-reactant is at least 20:1.
